(19) United States
(12) Patent Application Publication
(10) Pub. No.: US 2020/0212207 A1
(43) Pub. Date: Jul. 2, 2020

(54) MANUFACTURING METHOD OF JUNCTION FIELD EFFECT TRANSISTOR

(71) Applicant: RICHTEK TECHNOLOGY CORPORATION, Zhubei City (TW)

(72) Inventor: Tsung-Yi Huang, Hsinchu (TW)

(21) Appl. No.: 16/668,327

(22) Filed: Oct. 30, 2019

(30) Foreign Application Priority Data
Dec. 28, 2018 (TW) 107147888

(51) Int. Cl. H01L 29/66; H01L 29/06; H01L 29/10; H01L 29/808; H01L 21/265; H01L 21/762

(52) U.S. Cl. CPC H01L 29/66901; H01L 29/0653; H01L 21/762; H01L 29/808; H01L 21/26513; H01L 29/1058

(57) ABSTRACT

A manufacturing method of a junction field effect transistor (JFET) includes: providing a substrate having a first conductivity type, forming a channel region having a second conductive type, forming a field region having the first conductivity type, forming a gate having the first conductivity type, forming a source having the second conductive type, forming a drain having the second conductive type, and forming a lightly doped region having the second conductive type. The channel region is formed by a first ion implantation process step, and the lightly doped region is formed by a second ion implantation process step. The second ion implantation process step implants first conductivity type impurities into a part of the channel region.

### CROSS REFERENCE

The present invention claims priority to TW 107147888 filed on Dec. 28, 2018.

### BACKGROUND OF THE INVENTION

### Field of Invention

The present invention relates to a manufacturing method of a junction field effect transistor (JFET); particularly, it relates to such a manufacturing method which implants first conductivity type impurities in a part of a channel region having a second conductivity type to adjust a pinch-off voltage of the JFET.

### Description of Related Art

Please refer to FIG. 1A and FIG. 1B. FIG. 1A shows a top view of a conventional JFET 100. FIG. 1B shows a cross-section view of the conventional JFET 100 taken along A-A′ line of FIG. 1A. As shown in FIG. 1A and FIG. 1B, the conventional JFET 100 comprises: a substrate 11, a channel region 12, a field region 13, a gate 14, a source 15, a drain 16 and an isolation region 18. The substrate 11, the field region 13 and the gate 14 have a conductivity type of P-type, whereas, the channel region 12, the source 15 and the drain 16 have a conductivity type of N-type. Please refer to FIG. 1C, which is a diagram taken along W-W′ dashed line of FIG. 1B, showing N-type impurity concentration distribution (concentration by position). As shown in FIG. 1C, the N-type impurity concentration of the conventional JFET 100 along W-W′ dashed line is substantially constant, which means that N-type impurities are substantially uniformly distributed throughout the channel region 12. When the conventional JFET 100 operates in normal mode, by adjusting the voltage applied on the gate 14, the width of the depletion region formed between the channel region 12 and the field region 13 and between the channel region 12 and the substrate 11 can be adjusted, whereby the channel width of the channel region 12 is adjusted, to adjust the resistance between the source 15 and the drain 16. More specifically, a negative voltage having a higher absolute value applied on the gate 14 will result in a wider width of the depletion region of the channel region 12 and a smaller channel width of the channel region 12, causing the resistance between the source 15 and the drain 16 to be higher. Under a situation where the absolute value of the negative voltage applied on the gate 14 is greater than a threshold, the channel region 12 is entirely depleted, which is the so-called “pinched off”. This threshold voltage is defined as the “pinch-off voltage”.

When it is required for different JFETs having different pinch-off voltages to be manufactured on a same substrate, multiple different lithography process steps and ion implantation process steps will be needed to manufacture different channel regions of different impurity concentrations for different JFETs to have different pinch-off voltages.

The conventional JFET 100 has a drawback that the required multiple different manufacturing steps to adjust the pinch-off voltages are costly. As compared to the conventional JFET 100, the present invention is advantageous in that: first, the present invention provides a much simpler method for adjusting the pinch-off voltage of the JFET. Second, the present invention can manufacture different JFETs having different pinch-off voltages on a same substrate by same manufacturing steps, which is cost-effective and efficient.

### SUMMARY OF THE INVENTION

From one perspective, the present invention provides a manufacturing method of a junction field effect transistor (JFET), comprising: providing a substrate having a first conductivity type, wherein the substrate has a top surface; implanting second conductivity type impurities in the substrate below the top surface via a first ion implantation process step, to form a channel region, wherein the channel region has a second conductivity type opposite to the first conductivity type; forming a field region in the channel region below the top surface, wherein the field region has the first conductivity type; forming a gate in the field region below the top surface, wherein the gate has the first conductivity type; forming a source in the channel region below the top surface, wherein the source has the second conductivity type and is not located in the field region; forming a drain in the channel region below the top surface, wherein the drain has the second conductivity type and is not located in the field region, wherein the drain and the source are located outside two sides of the gate, respectively, wherein the drain and the source do not overlap each other; and implanting first conductivity type impurities in a part of the channel region below the top surface via a second ion implantation process step, to form a lightly doped region in the channel region, wherein the lightly doped region is between the source and the drain and has the second conductivity type, wherein a concentration of the second conductivity type impurities of the lightly doped region is lower than a concentration of the second conductivity type impurities of the channel region.

In one embodiment, the manufacturing method of the JFET further comprises: forming a plurality of isolation regions which are on and in contact with the top surface, wherein the plurality of isolation regions are located outside two sides of the gate, respectively, wherein one of the plurality of isolation regions is located between the source and the gate, whereas, another one of the plurality of isolation regions is located between the drain and the gate.

In one embodiment, the plurality of isolation regions include a local oxidation of silicon (LOCOS) structure or a shallow trench isolation (STI) structure.

In one embodiment, the lightly doped region is located completely right below the gate.

In one embodiment, the lightly doped region is located between the source and the gate, wherein the lightly doped region is not located right below of the source and the lightly doped region is not located right below of the gate.

In one embodiment, the lightly doped region is located between the drain and the gate, wherein the lightly doped region is not located right below of the drain and the lightly doped region is not located right below of the gate.

The objectives, technical details, features, and effects of the present invention will be better understood with regard to the detailed description of the embodiments below, with reference to the attached drawings.

### BRIEF DESCRIPTION OF THE DRAWINGS

FIG. 1A shows a top view of a conventional JFET 100.

FIG. 1B shows a cross-section view of the conventional JFET 100 taken along A-A′ line of FIG. 1A.

FIG. 1C shows a diagram illustrating N-type impurity concentration distribution.

FIGS. 2A-2K show a first embodiment of the present invention.

FIGS. 3A-3K show a second embodiment of the present invention.

FIGS. 4A-4K show a third embodiment of the present invention.

FIG. 5 shows a diagram illustrating a relationship between the width of a lightly doped region verses the pinch-off voltage of the JFET of the present invention.

FIGS. 6A-6C show exemplary diagrams illustrating OFF breakdown voltage, threshold voltage and ON breakdown voltage of the conventional JFET, respectively.

FIGS. 7A-7C show exemplary diagrams illustrating OFF breakdown voltage, threshold voltage and ON breakdown voltage of the JFET of the present invention, respectively.

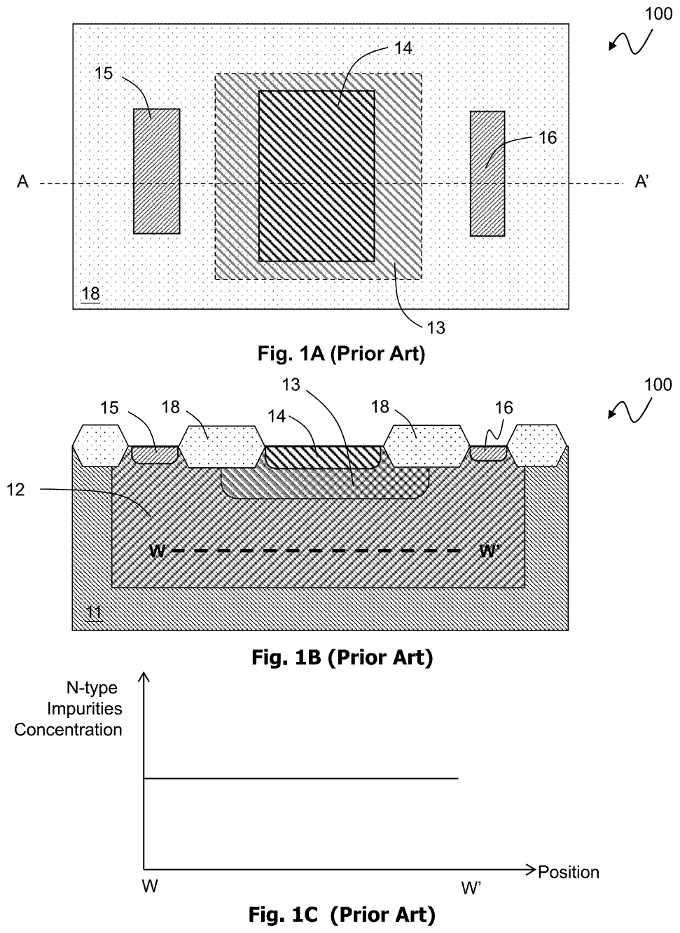

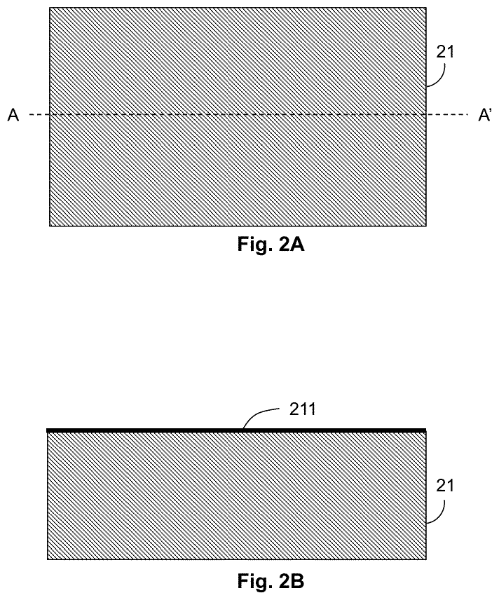

### DESCRIPTION OF THE PREFERRED EMBODIMENTS

The drawings as referred to throughout the description of the present invention are for illustration only, to show the interrelations among the process steps and the layers, while the shapes, thicknesses, and widths are not drawn in actual scale.

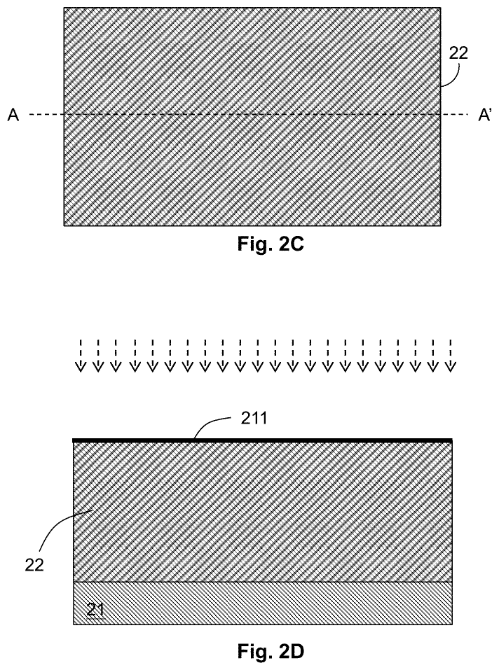

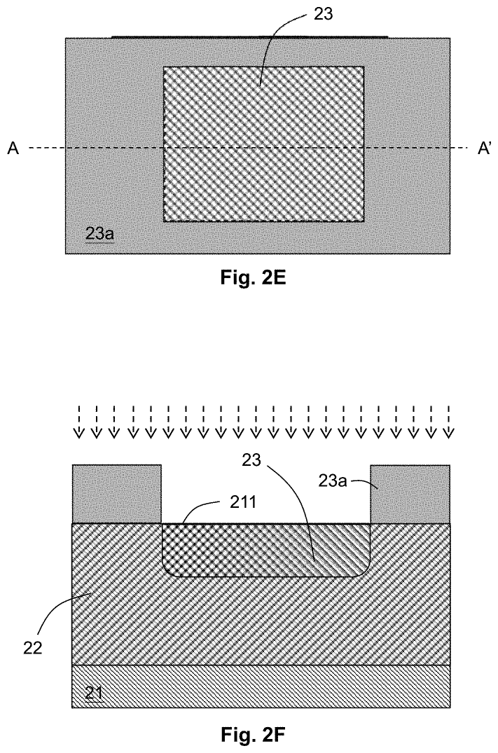

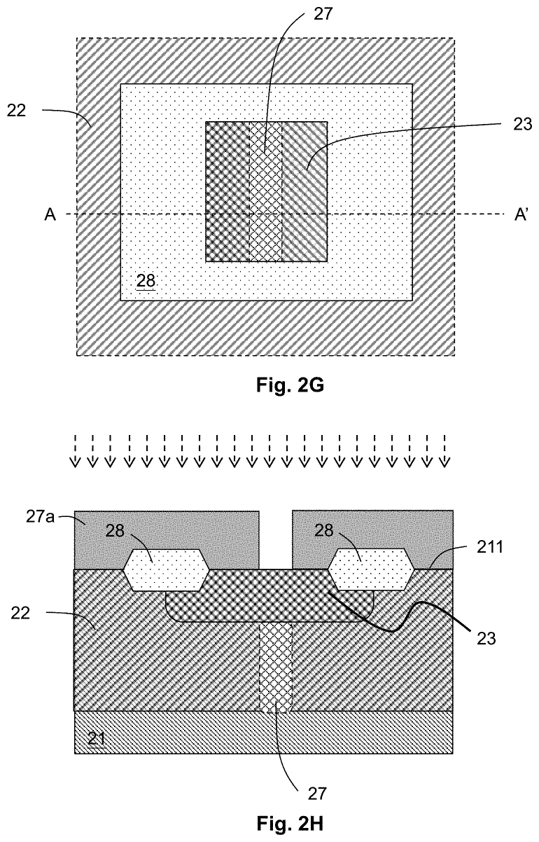

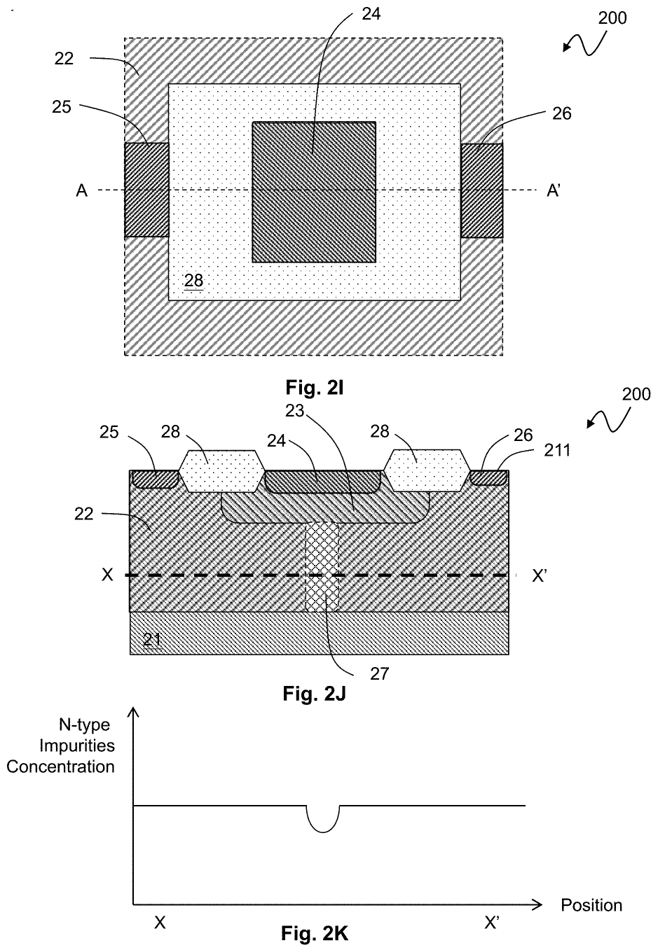

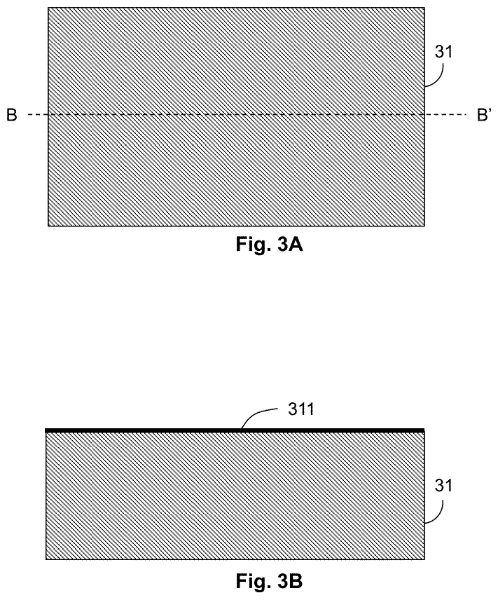

Please refer to FIGS. 2A-2K, which show a first embodiment of the present invention. FIGS. 2A-2J show a top view and a cross-section view of a manufacturing method of a JFET 200, respectively, according to an embodiment of the present invention. FIG. 2K shows a diagram (taken along X-X′ dashed line of FIG. 2J) illustrating N-type impurity concentration distribution (concentration by position). First, as shown in FIGS. 2A-2B, a substrate 21 is provided, which for example has a conductivity type of P-type. The substrate 21 has a top surface 211 (as indicated by the thick solid line shown in FIG. 2B). FIG. 2A shows a top view of the manufacturing method of the JFET 200. FIG. 2B shows a cross-section view of the manufacturing method of the JFET 200 taken along A-A′ line of FIG. 2A.

Next, as shown in FIGS. 2C-2D, a channel region 22 is formed below the top surface 211 in the substrate 21. The channel region 22 for example has a conductivity type of N-type which is opposite to the conductivity type of the substrate 21 (which is P-type in this example). FIG. 2C shows atop view of the manufacturing method of the JFET 200. FIG. 2D shows a cross-section view of the manufacturing method of the JFET 200 taken along A-A′ line of FIG. 2C.

Next, as shown in FIGS. 2E-2F, in this embodiment, a field region 23 can be formed by, for example but not limited to, a lithography process step and an ion implantation process step, wherein the lithography process step includes forming a photo-resist layer 23a as a mask, and the ion implantation process step implants P-type impurities in the defined region in the form of accelerated ions (e.g., as shown by the dashed arrows in FIG. 2F), to form the field region 23 in the channel region 22 below the top surface 211. The field region 23 for example has a conductivity type of P-type. FIG. 2E shows a top view of the manufacturing method of the JFET 200. FIG. 2F shows a cross-section view of the manufacturing method of the JFET 200 taken along A-A′ line of FIG. 2E.

Next, as shown in FIGS. 2G-2H, in this embodiment, a lightly doped region 27 can be formed by, for example but not limited to, a lithography process step and an ion implantation process step, wherein the lithography process step includes forming a photo-resist layer 27a as a mask, and the ion implantation process step implants P-type impurities in the defined region in the form of accelerated ions (e.g., as shown by the dashed arrows in FIG. 2H), to compensate N-type impurities in the channel region 22, thus forming the lightly doped region 27 in the channel region 22 below the top surface 211. The lightly doped region 27 is located between the source 25 and the drain 26 which are to be formed later. The lightly doped region 27 for example has a conductivity type of N-type. The N-type impurity concentration of the lightly doped region 27 is lower than the N-type impurity concentration of the channel region 22. In this embodiment, the lightly doped region 27 is located completely right below the gate 24 which is to be formed later.

Note that, in the ion implantation process step to form the lightly doped region 27, P-type impurities are implanted in the channel region 22 having N-type to reduce the N-type impurity concentration of a part of the channel region 22. This step utilizes a semiconductor compensation effect which is, when a semiconductor layer is doped with both P-type impurities and N-type impurities, the minority impurities will be neutralized by the majority impurities, and the rest of the majority impurities will become the conductivity type of the semiconductor layer, but with a lower concentration.

Next, still referring to FIGS. 2G-2H, an isolation region 28 is formed by, for example but not limited to, an oxidation process step. The isolation region 28 can be, for example but not limited to, a local oxidation of silicon (LOCOS) structure (as shown in FIGS. 2G-2H) or a shallow trench isolation (STI) structure. In one embodiment, the isolation regions 28 are plural, which are formed for example on and in contact with the top surface 211, and located outside two sides of the gate 24, respectively. One of the isolation regions 28 is located between the source 25 and the gate 24 (which are to be formed later), whereas, another one of the isolation regions 28 is located between the drain 26 and the gate 24 which are to be formed later). FIG. 2G shows a top view of the manufacturing method of the JFET 200. FIG. 2H shows a cross-section view of the manufacturing method of the JFET 200 taken along A-A′ line of FIG. 2G.

Next, as shown in FIGS. 2I-2J, a gate 24 can be formed by, for example but not limited to, a lithography process step and an ion implantation process step, wherein the lithography process step includes forming a photo-resist layer (not shown) as a mask, and the ion implantation process step implants P-type impurities in the defined region in the form of accelerated ions, to form the gate 24 having P-type conductivity in the field region 23 below the top surface 211. Next, as shown in FIGS. 2I-2J, the source 25 and the drain 26 can be formed by, for example but not limited to, a lithography process step and an ion implantation process step, wherein the lithography process step includes forming a photo-resist layer (not shown) as a mask, and the ion implantation process step implants N-type impurities in the defined region in the form of accelerated ions, to form the source 25 and the drain 26 having N-type conductivity in the channel region 22 below the top surface 211. The source 25 and the drain 26 are not located in the field region 23. The source 25 and the drain 26 are located outside two sides of the field region 23, respectively. The source 25 and the drain 26 do not overlap each other. FIG. 21 shows a top view of the manufacturing method of the JFET 200. FIG. 2J shows a cross-section view of the manufacturing method of the JFET 200 taken along A-A′ line of FIG. 21.

FIG. 2K shows a diagram (taken along X-X′ dashed line of FIG. 2J) illustrating N-type impurity concentration distribution (concentration by position). Because the lightly doped region 27 is formed with semiconductor compensation effect by implanting P-type impurities the lightly doped region 27, the N-type impurity concentration of apart (where the lightly doped region 27 is formed) of the channel region 22 is lower than the N-type impurity concentration of other parts of the channel region 22, so that the pinch-off voltage of the JFET 200 can be adjusted as desired.

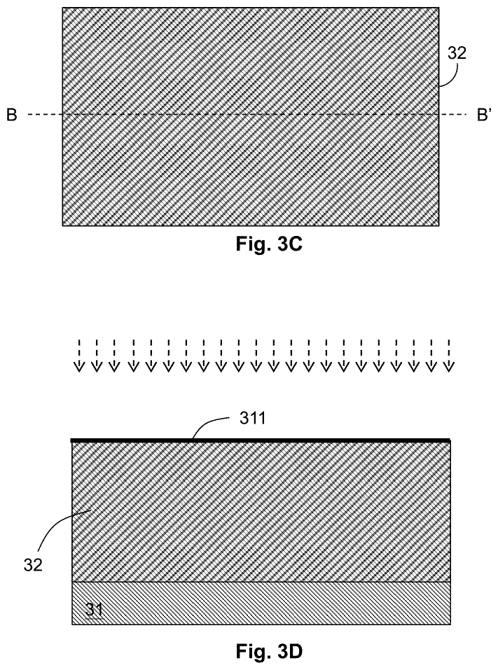

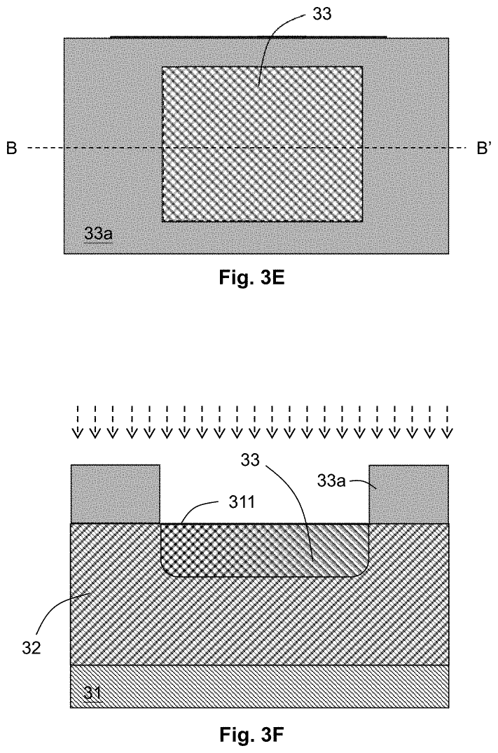

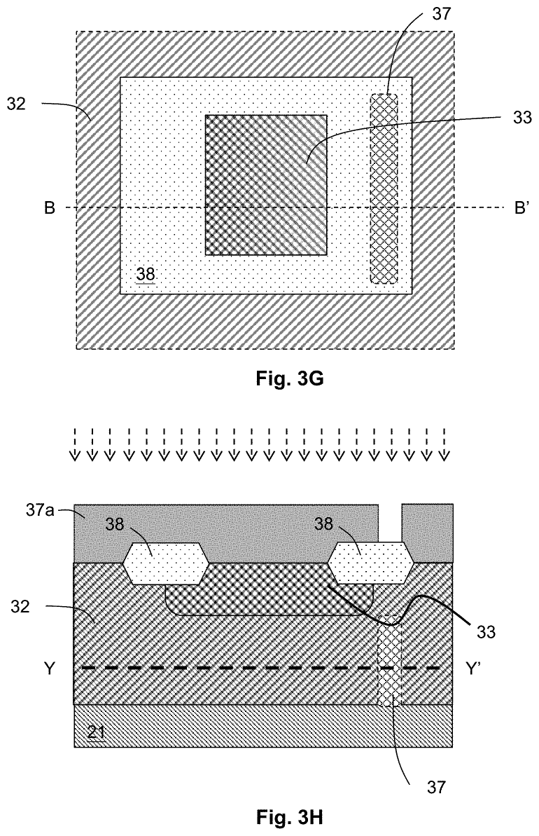

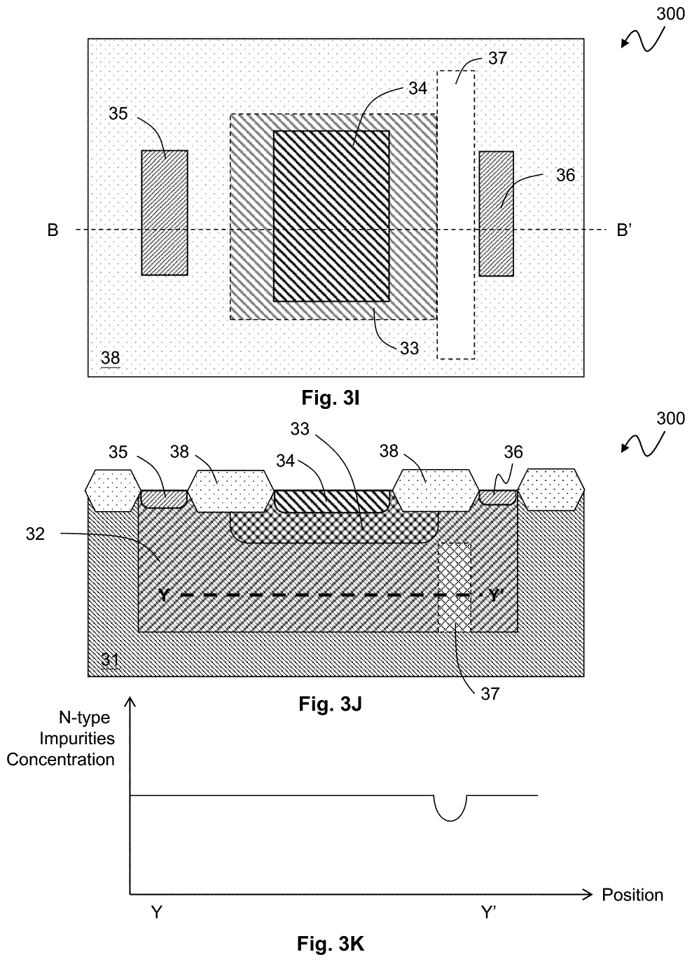

Please refer to FIGS. 3A-3K, which show a second embodiment of the present invention. FIGS. 3A-3J show a top view and a cross-section view of a manufacturing method of a JFET 300, respectively, according to an embodiment of the present invention. FIG. 3K shows a diagram (taken along Y-Y′ dashed line of FIG. 3J) illustrating N-type impurity concentration distribution (concentration by position). First, as shown in FIGS. 3A-3B, a substrate 31 is provided, which for example has a conductivity type of P-type. The substrate 31 has a top surface 311 (as indicated by the thick solid line shown in FIG. 3B). FIG. 3A shows a top view of the manufacturing method of the JFET 300. FIG. 2B shows a cross-section view of the manufacturing method of the JFET 300 taken along B-B′ line of FIG. 3A.

Next, as shown in FIGS. 3C-3D, a channel region 32 is formed below the top surface 311 in the substrate 31. The channel region 32 for example has a conductivity type of N-type which is opposite to the conductivity type of the substrate 31 (which is P-type in this example). FIG. 3C shows a top view of the manufacturing method of the JFET 300. FIG. 3D shows a cross-section view of the manufacturing method of the JFET 300 taken along B-B′ line of FIG. 3C.

Next, as shown in FIGS. 3E-3F, in this embodiment, a field region 33 can be formed by, for example but not limited to, a lithography process step and an ion implantation process step, wherein the lithography process step includes forming a photo-resist layer 33a as a mask, and the ion implantation process step implants P-type impurities in the defined region in the form of accelerated ions (e.g., as shown by the dashed arrows in FIG. 3F), to form the field region 33 in the channel region 32 below the top surface 311. The field region 33 for example has a conductivity type of P-type. FIG. 3E shows a top view of the manufacturing method of the JFET 300. FIG. 3F shows a cross-section view of the manufacturing method of the JFET 300 taken along B-B′ line of FIG. 3E.

Next, as shown in FIGS. 3G-3H, in this embodiment, a lightly doped region 37 can be formed by, for example but not limited to, a lithography process step and an ion implantation process step, wherein the lithography process step includes forming a photo-resist layer 37a as a mask, and the ion implantation process step implants P-type impurities in the defined region in the form of accelerated ions (e.g., as shown by the dashed arrows in FIG. 3H), to compensate N-type impurities in the channel region 32, thus forming the lightly doped region 37 in the channel region 32 below the top surface 311. The lightly doped region 37 is between the source 35 and the drain 36 which are to be formed later. The lightly doped region 37 for example has a conductivity type of N-type. The N-type impurity concentration of the lightly doped region 37 is lower than the N-type impurity concentration of the channel region 32. In this embodiment, the lightly doped region 37 is entirely located between the drain 36 and the gate 34 which are to be formed later. Note that, the lightly doped region 37 is neither located right below the drain 36, nor located right below the gate 34.

Note that, in the ion implantation process step to form the lightly doped region 37, P-type impurities are implanted in the channel region 32 having N-type to reduce the N-type impurity concentration of a part of the channel region 32. This step utilizes the semiconductor compensation effect.

Next, still referring to FIGS. 3G-3H, an isolation region 38 can be formed by, for example but not limited to, an oxidation process step. The isolation region 38 can be, for example but not limited to, a local oxidation of silicon (LOCOS) structure (as shown in FIGS. 3G-3H) or a shallow trench isolation (STI) structure. In one embodiment, the isolation regions 38 are plural, which are formed for example on and in contact with the top surface 311, and located outside two sides of the gate 34, respectively. One of the isolation regions 38 is located between the source 35 and the gate (which are to be formed later), whereas, another one of the isolation regions 38 is located between the drain 36 and the gate 34 which are to be formed later). FIG. 3G shows a top view of the manufacturing method of the JFET 300. FIG. 3H shows a cross-section view of the manufacturing method of the JFET 300 taken along B-B′ line of FIG. 3G.

Next, as shown in FIGS. 3I-3J, a gate 34 can be formed by, for example but not limited to, a lithography process step and an ion implantation process step, wherein the lithography process step includes forming a photo-resist layer (not shown) as a mask, and the ion implantation process step implants P-type impurities in the defined region in the form of accelerated ions, to form the gate 34 having P-type conductivity in the field region 33 below the top surface 311. Next, as shown in FIGS. 3I-3J, in this embodiment, a source 35 and a drain 36 can be formed by, for example but not limited to, a lithography process step and an ion implantation process step, wherein the lithography process step includes forming a photo-resist layer (not shown) as a mask, and the ion implantation process step implants N-type impurities in the defined region in the form of accelerated ions, to form the source 35 and the drain 36 having N-type conductivity in the channel region 32 below the top surface 311. The source 35 and the drain 36 are not located in the field region 33. The source 35 and the drain 36 are located outside two sides of the field region 33, respectively. The source 35 and the drain 36 do not overlap each other. FIG. 31 shows a top view of the manufacturing method of the JFET 300. FIG. 3J shows a cross-section view of the manufacturing method of the JFET 300 taken along B-B′ line of FIG. 31.

FIG. 3K shows a diagram (taken along Y-Y′ dashed line of FIG. 3J) illustrating N-type impurity concentration distribution (concentration by position). Because the lightly doped region 37 is formed with semiconductor compensation effect by implanting P-type impurities the lightly doped region 37, the N-type impurity concentration of apart (where the lightly doped region 37 is formed) of the channel region 32 is lower than the N-type impurity concentration of other parts of the channel region 32, so that the pinch-off voltage of the JFET 300 can be adjusted as desired.

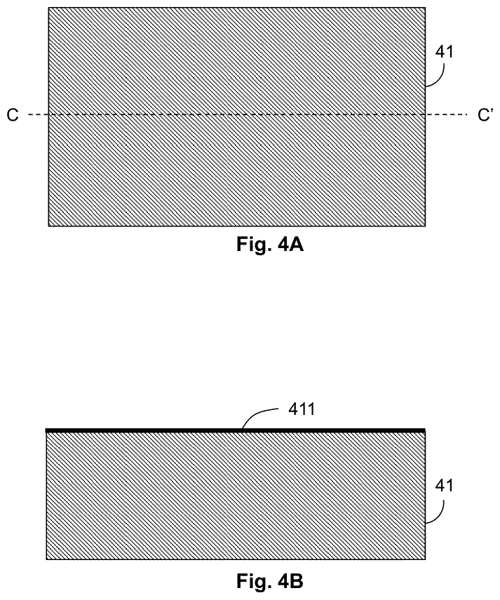

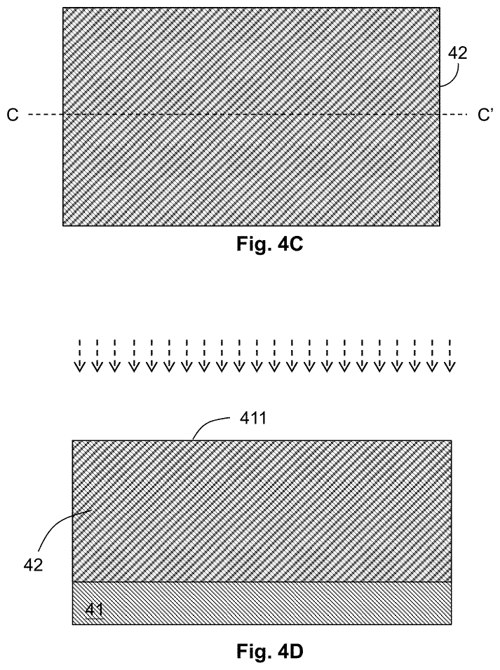

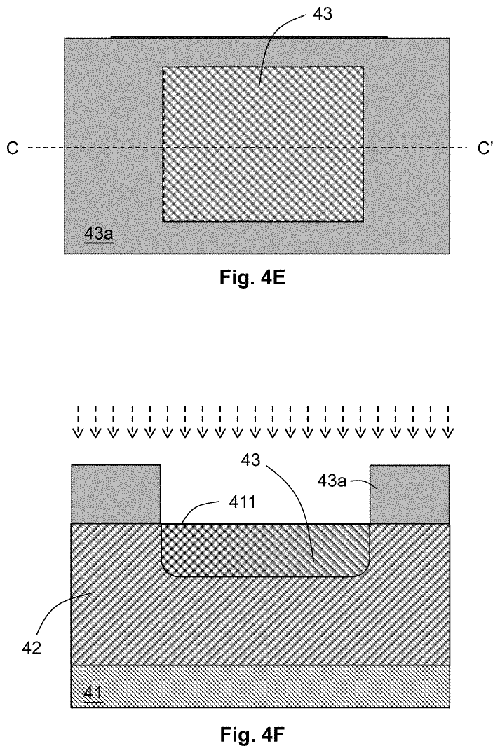

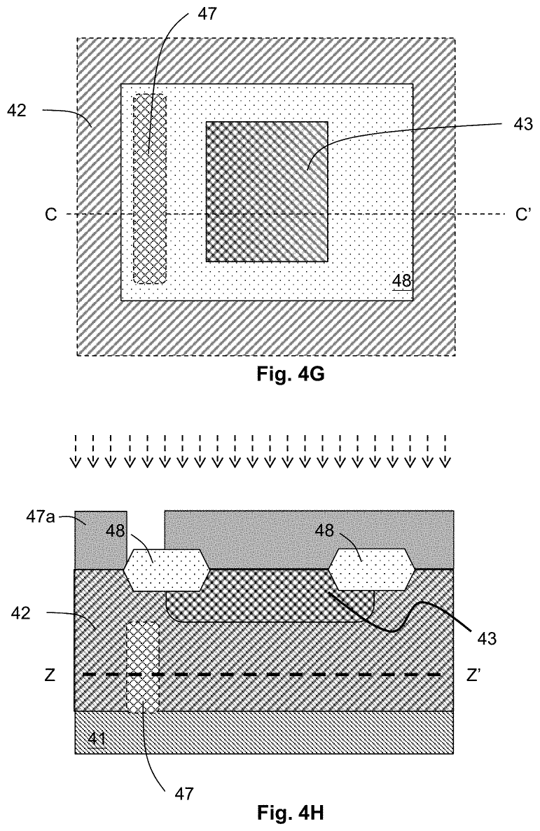

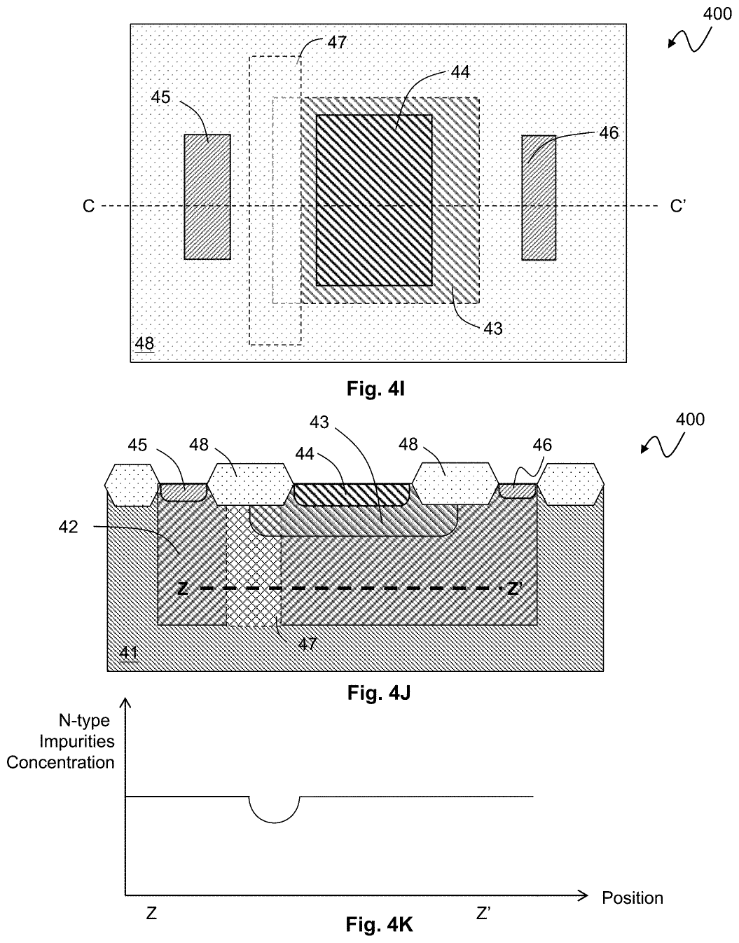

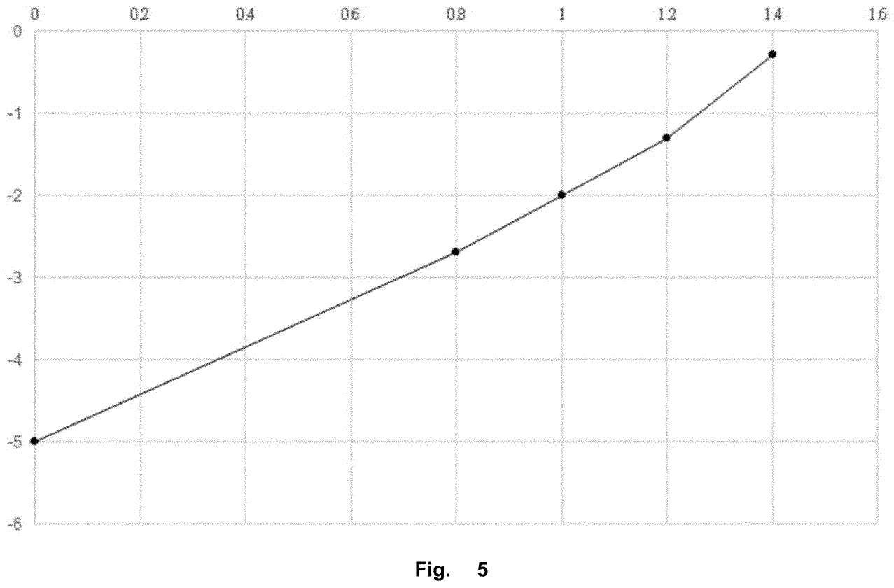

Please refer to FIGS. 4A-4K, which show a third embodiment of the present invention. FIGS. 4A-4J show a top view and a cross-section view of a manufacturing method of a JFET 400, respectively, according to an embodiment of the present invention. FIG. 4K shows a diagram (taken along Z-Z′ dashed line of FIG. 4J) illustrating N-type impurity concentration distribution (concentration by position). First, as shown in FIGS. 4A-4B, a substrate 41 is provided, which for example has a conductivity type of P-type. The substrate 41 has a top surface 411 (as indicated by the thick solid line shown in FIG. 4B). FIG. 4A shows a top view of the manufacturing method of the JFET 400. FIG. 4B shows a cross-section view of the manufacturing method of the JFET 400 taken along C-C′ line of FIG. 4A.

Next, as shown in FIGS. 4C-4D, a channel region 42 is formed below the top surface 411 in the substrate 41. The channel region 42 for example has a conductivity type of N-type which is opposite to the conductivity type of the substrate 41 (which is P-type in this example). FIG. 4C shows a top view of the manufacturing method of the JFET 400. FIG. 4D shows a cross-section view of the manufacturing method of the JFET 400 taken along C-C′ line of FIG. 4C.

Next, as shown in FIGS. 4E-4F, in this embodiment, a field region 43 can be formed by, for example but not limited to, a lithography process step and an ion implantation process step, wherein the lithography process step includes forming a photo-resist layer 43a as a mask, and the ion implantation process step implants P-type impurities in the defined region in the form of accelerated ions (e.g., as shown by the dashed arrows in FIG. 4F), to form the field region 43 in the channel region 42 below the top surface 411. The field region 43 for example has a conductivity type of P-type. FIG. 4E shows a top view of the manufacturing method of the JFET 400. FIG. 4F shows a cross-section view of the manufacturing method of the JFET 400 taken along C-C′ line of FIG. 4E.

Next, as shown in FIGS. 4G-4H, in this embodiment, a lightly doped region 47 can be formed by, for example but not limited to, a lithography process step and an ion implantation process step, wherein the lithography process step includes forming a photo-resist layer 47a as a mask, and the ion implantation process step implants P-type impurities in the defined region in the form of accelerated ions (e.g., as shown by the dashed arrows in FIG. 4H), to compensate N-type impurities in the channel region 42, thus forming the lightly doped region 47 in the channel region 42 below the top surface 411. The lightly doped region 47 is located between the source 45 and the drain 46 which are to be formed later. The lightly doped region 47 for example has a conductivity type of N-type. The N-type impurity concentration of the lightly doped region 47 is lower than the N-type impurity concentration of the channel region 42. In this embodiment, the lightly doped region 47 is entirely located between the source 45 and the gate 44 which are to be formed later. Note that, the lightly doped region 47 is neither located right below the source 45 nor located right below the gate 44.

Note that, in the ion implantation process step to form the lightly doped region 47, P-type impurities are implanted in the channel region 42 having N-type to reduce the N-type impurity concentration of a part of the channel region 42. This step utilizes the semiconductor compensation effect.

Next, still referring to FIGS. 4G-4H, an isolation region 48 can be formed by, for example but not limited to, an oxidation process step. The isolation region 48 can be, for example but not limited to, a local oxidation of silicon (LOCOS) structure (as shown in FIGS. 4G-4H) or a shallow trench isolation (STI) structure. In one embodiment, the isolation regions 48 are plural, which are formed for example on and in contact with the top surface 411, and located outside two sides of the gate 44, respectively. One of the isolation regions 48 is located between the source 45 and the gate (which are to be formed later), whereas, another one of the isolation regions 48 is located between the drain 46 and the gate 44 which are to be formed later). FIG. 4G shows a top view of the manufacturing method of the JFET 400. FIG. 4H shows a cross-section view of the manufacturing method of the JFET 400 taken along B-B′ line of FIG. 4G.

Next, as shown in FIGS. 4I-4J, in this embodiment, a gate 44 can be formed by, for example but not limited to, a lithography process step and an ion implantation process step, wherein the lithography process step includes forming a photo-resist layer (not shown) as a mask, and the ion implantation process step implants P-type impurities in the defined region in the form of accelerated ions, to form the gate 44 having P-type conductivity in the field region 43 below the top surface 411. Next, as shown in FIGS. 4I-4J, in this embodiment, a source 45 and a drain 46 can be formed by, for example but not limited to, a lithography process step and an ion implantation process step, wherein the lithography process step includes forming a photo-resist layer (not shown) as a mask, and the ion implantation process step implants N-type impurities in the defined region in the form of accelerated ions, to form the source 45 and the drain 46 having N-type conductivity in the channel region 42 below the top surface 411. The source 45 and the drain 46 are not located in the field region 43. The source 45 and the drain 46 are located outside two sides of the field region 33, respectively. The source 45 and the drain 46 do not overlap each other. FIG. 41 shows a top view of the manufacturing method of the JFET 400. FIG. 4J shows a cross-section view of the manufacturing method of the JFET 400 taken along C-C′ line of FIG. 41.

FIG. 4K shows a diagram (taken along Z-Z′ dashed line of FIG. 4J) illustrating N-type impurity concentration distribution (concentration by position). Because the lightly doped region 47 is formed with semiconductor compensation effect by implanting P-type impurities the lightly doped region 47, the N-type impurity concentration of apart (where the lightly doped region 47 is formed) of the channel region 42 is lower than the N-type impurity concentration of other parts of the channel region 42, so that the pinch-off voltage of the JFET 400 can be adjusted as desired.

Please refer to FIG. 5, which shows a diagram illustrating a relationship between the width of a lightly doped region verses the pinch-off voltage of the JFET of the present invention, taking the JFET 200 of the first embodiment as an example. In FIG. 5, the horizontal axis denotes the width of the lightly doped region 27 and the vertical axis denotes the pinch-off voltage of the JFET 200. As shown in FIG. 5, the pinch-off voltage of the JFET 200 according to the present invention can be adjusted by adjusting the width of the lightly doped region 27; in the present invention, it is not required to perform multiple different manufacturing process steps as in the prior art, so the present invention is cost-effective and efficient.

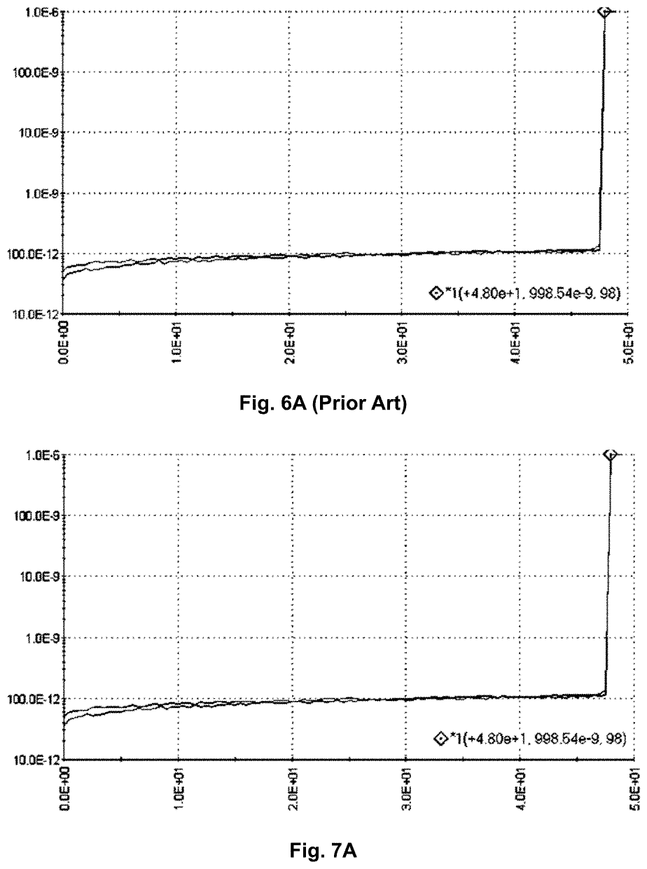

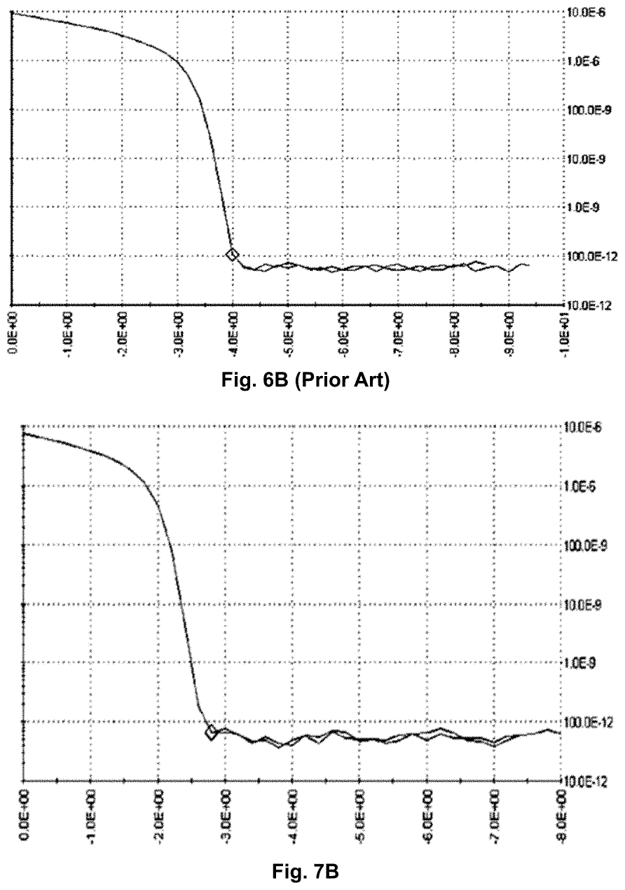

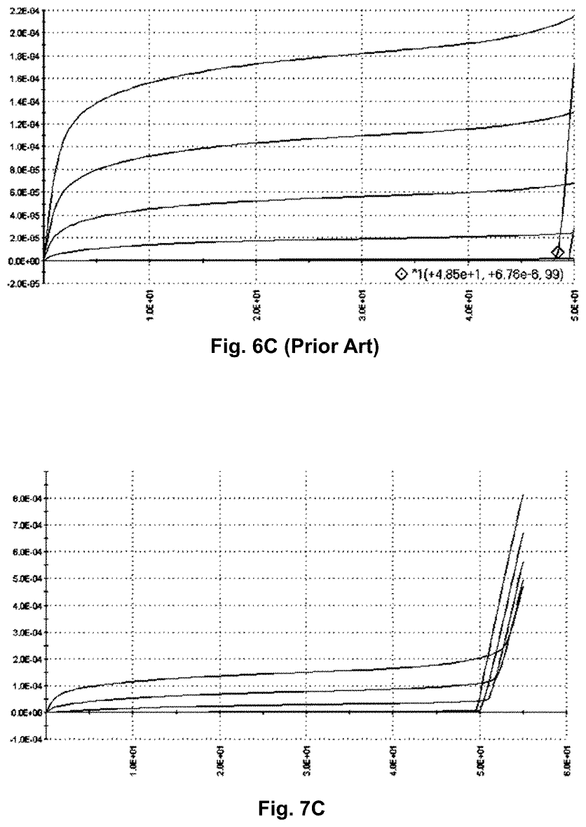

Please refer to FIGS. 6A-6C and FIGS. 7A-7C. FIGS. 6A-6C show exemplary diagrams illustrating OFF breakdown voltage, threshold voltage and ON breakdown voltage of the conventional JFET, respectively. FIGS. 7A-7C show exemplary diagrams illustrating OFF breakdown voltage, threshold voltage and ON breakdown voltage of the JFET of the present invention, respectively. Note that the JFET of FIGS. 7A-7C and the conventional JFET of FIGS. 6A-6C are manufactured on a same substrate. A comparison between FIG. 6A and FIG. 7A shows that both the conventional JFET of FIG. 6A and the JFET of FIG. 7A have an OFF breakdown voltage of about 48V. A comparison between FIG. 6B and FIG. 7B shows that, while the conventional JFET of FIG. 6B has a threshold voltage of about −4V, the JFET of FIG. 7B has a threshold voltage of about −2.7V. This comparison demonstrates that the present invention can manufacture different JFETs having different threshold voltages on one same substrate by the same manufacturing steps. A comparison between FIG. 6C and FIG. 7C shows that both the conventional JFET of FIG. 6C and the JFET of FIG. 7C have an ON breakdown voltage greater than about 50V. This comparison demonstrates that the present invention is able to adjust the threshold voltage without compromising other electrical characteristics of the JFET.

The present invention has been described in considerable detail with reference to certain preferred embodiments thereof. It should be understood that the description is for illustrative purpose, not for limiting the scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, other process steps or structures, such as a deep well region, may be added. For another example, the lithography process step is not limited to the mask technology but it can also include electron beam lithography etc. It is not limited for each of the embodiments described hereinbefore to be used alone; under the spirit of the present invention, two or more of the embodiments described hereinbefore can be used in combination. For example, two or more of the embodiments can be used together, or, a part of one embodiment can be used to replace a corresponding part of another embodiment. In view of the foregoing, the spirit of the present invention should cover all such and other modifications and variations, which should be interpreted to fall within the scope of the following claims and their equivalents. Note that the first conductivity type and the second conductivity type can be P-type or N-type. That is, when the first conductivity type is P-type, the second conductivity type is N-type. On other hand, when the first conductivity type is of N-type, the second conductivity type is of P-type.

What is claimed is:

1. A manufacturing method of a junction field effect transistor (JFET), comprising:
providing a substrate having a first conductivity type, wherein the substrate has a top surface;
implanting second conductivity type impurities in the substrate below the top surface via a first ion implantation process step, to form a channel region, wherein the channel region has a second conductivity type opposite to the first conductivity type;
forming a field region in the channel region below the top surface, wherein the field region has the first conductivity type;
forming a gate in the field region below the top surface, wherein the gate has the first conductivity type;
forming a source in the channel region below the top surface, wherein the source has the second conductivity type and is not located in the field region;
forming a drain in the channel region below the top surface, wherein the drain has the second conductivity type and is not located in the field region, wherein the drain and the source are located outside two sides of the gate, respectively, wherein the drain and the source do not overlap each other; and
implanting first conductivity type impurities in a part of the channel region below the top surface via a second ion implantation process step, to form a lightly doped region in the channel region, wherein the lightly doped region is between the source and the drain and has the second conductivity type, wherein a concentration of the second conductivity type impurities of the lightly doped region is lower than a concentration of the second conductivity type impurities of the channel region.

2. The manufacturing method of the JFET of claim 1, further comprising:
forming a plurality of isolation regions which are on and in contact with the top surface, wherein the plurality of isolation regions are located outside two sides of the gate, respectively, wherein one of the plurality of isolation regions is located between the source and the gate, whereas, another one of the plurality of isolation regions is located between the drain and the gate.

3. The manufacturing method of the JFET of claim 2, wherein the plurality of isolation regions include a local oxidation of silicon (LOCOS) structure or a shallow trench isolation (STI) structure.

4. The manufacturing method of the JFET of claim 1, wherein the lightly doped region is located completely right below the gate.

5. The manufacturing method of the JFET of claim 1, wherein the lightly doped region is located between the source and the gate, wherein the lightly doped region is not located right below of the source and the lightly doped region is not located right below of the gate.

6. The manufacturing method of the JFET of claim 1, wherein the lightly doped region is located between the drain and the gate, wherein the lightly doped region is not located right below of the drain and the lightly doped region is not located right below of the gate.
